(19) United States
(12) Patent Application Publication
(10) Pub. No.: US 2007/0072356 A1
(43) Pub. Date: Mar. 29, 2007

(54) METHOD FOR REDUCING POSITIVE CHARGES ACCUMULATED ON CHIPS DURING ION IMPLANTATION

(76) Inventors: Hui-Shen Shih, Changhua Hsien (TW); Kuan-I Huang, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,906

(22) Filed: Sep. 28, 2005

(51) Int. Cl. H01L 21/426

(52) U.S. Cl. 438/202; 438/516

(57) ABSTRACT

In the plasma etching process of the integrated circuit, a portion of the charges from the plasma accumulates on the semiconductor device through the conductive portion of the integrated circuit so as to damage the device. The phenomenon mentioned above is so called antenna effect. In order to decreased the number of the accumulated charges caused by antenna effect and to alleviate the damage of the accumulated charges on the device, the conductive photoresist is used in the plasma etching process. The method for applying the conductive photoresist in the integrated circuit process is as same as the application method for using the well known standard photoresist.

### BACKGROUND OF THE INVENTION

1. Field of the Invention

The present invention generally relates to a fabrication method for semiconductor devices, in particular, to a method for reducing positive charges accumulated on chips during ion implantation.

2. Description of Related Art

The ion implantation process is in general applied to form doped regions in the semiconductor substrates. During the ion implantation process, the exposed substrate is implanted with desired dopants through the patterned photoresist layer. Usually, the dopants (i.e. ions) used in the ion implantation process carry positive charges. Hence, after implanting dopants to the substrate, positive charges are accumulated on the surface of the chip.

FIG. 1 is a cross-sectional view of a MOS transistor during the ion implantation process. As shown in FIG. 1, the MOS transistor including a gate 102 and spacers 104 is formed on a substrate 100. The patterned photoresist layer 106 is used as a mask, and an ion implantation process 108 is performed to form doped regions 110 (as source/drain). If the transmittance (TR) of the patterned photoresist layer 106 is very low (that is, the area of the substrate 100 covered by the patterned photoresist layer 106 is much larger than the exposed area of the substrate 100), large amount of positive charges may be accumulated on the exposed surface of the substrate 100, which leads to the eruption of the edge regions 111 of the patterned photoresist layer 106, so-called volcano effects, and damages to the MOS transistor.

FIG. 2 is a partial cross-sectional view of a bipolar complimentary MOS (BiCMOS) transistor during the ion implantation process. As shown in FIG. 2, positive charges 208 can not be discharged into the P-type silicon substrate 200 because of the P-N junction 206 formed between the N-type epitaxial silicon layer 204 and the P-type substrate 200.

FIG. 3 is a partial display view of the wafer in the ion implantation system during the ion implantation process. The wafer 310 is placed on the platform 302 of the ion implantation system 300. In order to neutralize the accumulated positive charges, an aluminum cover 304 is set within the ion implantation system 300. During the ion implantation process, secondary electrons 308 are produced through bombardments of ion beams on the aluminum cover 304 and the electrons will neutralize the accumulated positive charges. However, if the current of the ion beam is not large enough, the produced electrons are not sufficient to completely neutralize the accumulated positive charges. Therefore, it is desired to develop alternative methods efficient for reducing positive charges accumulated on the chip surface during ion implantation.

### SUMMARY OF THE INVENTION

Accordingly, the present invention is directed to a method for reducing positive charges accumulated on the chip surface during ion implantation, by using a conductive photoresist pattern as a mask for an ion implantation process.

The present invention is directed to a method of fabricating a bipolar complimentary MOS (BiCMOS) transistor. By using a conductive photoresist pattern as a mask, the ion implantation process for forming doped regions is performed without the volcano effects.

According to an embodiment of the present invention, a method for reducing positive charges accumulated on a chip during an ion implantation process is provided. After providing a substrate, a conductive photoresist pattern is formed over the substrate, and the conductive photoresist pattern exposes a portion of the substrate. Using the conductive photoresist pattern as a mask, an ion implantation process is performed to the substrate, so as to form a plurality of doped regions in the substrate. Afterwards, the conductive photoresist pattern is removed.

According to one embodiment, a material of the conductive photoresist pattern comprises at least a conductive resin, a solvent and a selectively photosensitive material. The conductive resin includes 3-hexylthiophene-3-thiophene-ethane methacrylate copolymer, for example. The solvent includes acetonitrile, while the photosensitive material includes gold chloride, for example. Moreover, the conductive photoresist pattern has a resistance smaller or equivalent to 10⁻⁶ ohm-cm, for example.

By using the conductive photoresist pattern as a mask, the positive charges accumulated during the ion implantation process can be discharged to external environments. Therefore, local eruptions resulting from the charges accumulated on the chip surface can be avoided.

According to another embodiment of the present invention, a method of fabricating a bipolar complementary metal-oxide-semiconductor (MOS) transistor, comprising forming a complementary MOS transistor and a bipolar transistor on a substrate is provided. The method is characterized in that the step of forming heavily doped regions of the bipolar complementary MOS transistor comprises using a conductive photoresist pattern as a mask for an ion implantation process for preventing local eruptions of the bipolar complementary MOS transistor due to positive charges.

According to another embodiment, the heavily doped regions may be source/drain regions, collector contacts, emitters, bases or base contacts.

By using the conductive photoresist pattern as a mask for one or more ion implantation processes, the positive charges accumulated during the ion implantation process can be discharged to external environments. Therefore, the volcano effects resulting from the accumulated charges can be alleviated.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a MOS transistor during the ion implantation process.

FIG. 2 is a partial cross-sectional view of a BiCMOS transistor during the ion implantation process.

FIG. 3 is a partial display view of the wafer in the ion implantation system during the ion implantation process.

FIG. 4 is a cross-sectional view of a MOS transistor during the ion implantation process according to one preferred embodiment of this invention.

FIGS. 5A-5D are cross-sectional views of the process steps for fabricating a BiCMOS transistor according to another preferred embodiment of this invention.

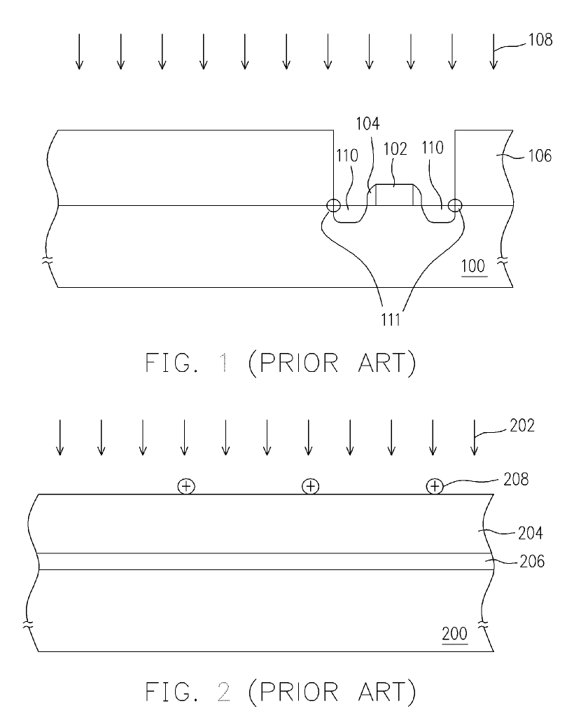

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

FIG. 4 is a cross-sectional view of a MOS transistor during the ion implantation process according to one preferred embodiment of this invention. The MOS transistor includes a gate 402 and spacers 404 formed on a substrate 400. The substrate 400 may further include other electronic components and will not be depicted in the figure. A conductive photoresist pattern 406 is formed over the substrate 400 and exposes a portion of the substrate 400. The material of the conductive photoresist pattern 406 includes at least a conductive resin, a solvent and a selectively photosensitive material. The conductive resin can be 3-hexylthiophene-3-thiophene-ethane methacrylate copolymer, for example. The solvent can be acetonitrile, and the photosensitive material can be gold chloride, for example. The conductive photoresist pattern 406 has a resistance smaller or equivalent to 10⁻⁶ ohm-cm. For example, the conductive photoresist pattern 406 can be either a positive photoresist or negative photoresist.

Referring to FIG. 4, the conductive photoresist pattern 406 is used as a mask during the ion implantation process 408, and doped regions 410 are formed in the exposed substrate 400. The doped regions 410 may function as source/drain regions and the concentration of the doped regions 410 is, for example, about 10¹⁸-10²⁰/cm³. After the ion implantation process 408, the conductive photoresist pattern 406 is removed.

During the above ion implantation process 408, positive charges from the ions can be discharged by the conductive photoresist pattern 406 and will not be accumulated between the exposed substrate 400 and the conductive photoresist pattern 406. Therefore, the eruption will not occur in the edge regions 411 of the conductive photoresist pattern 406.

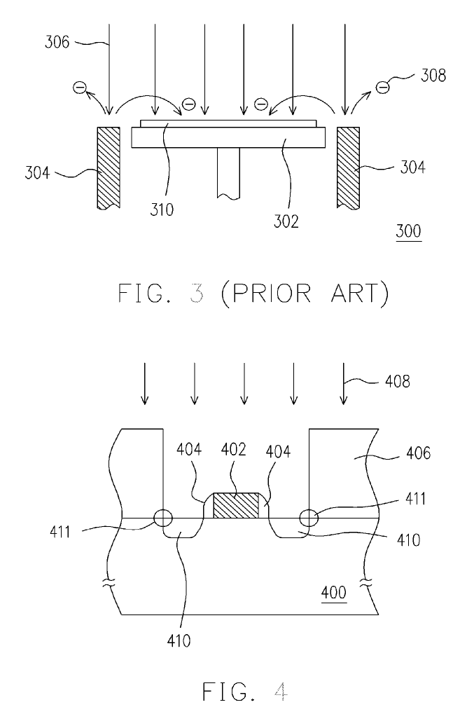

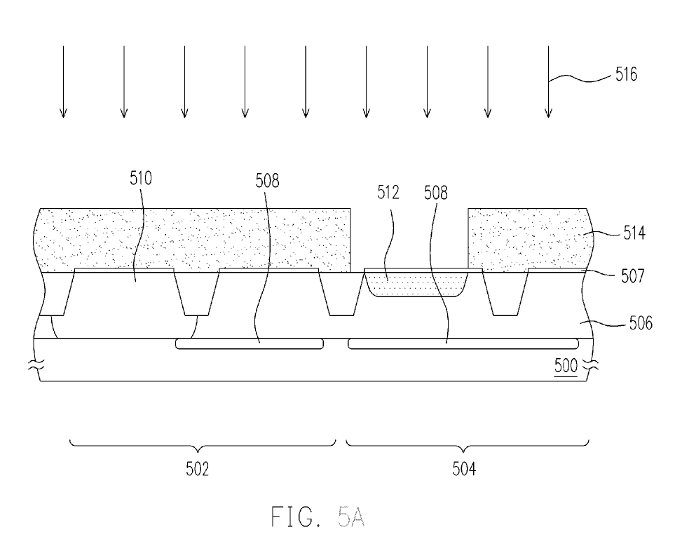

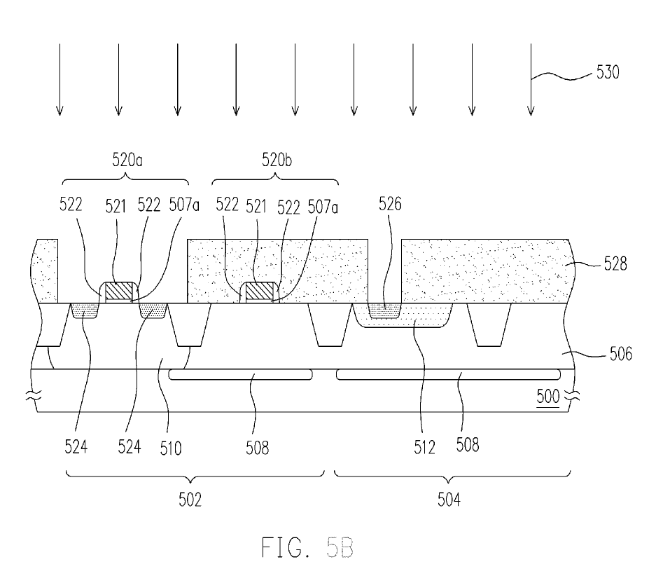

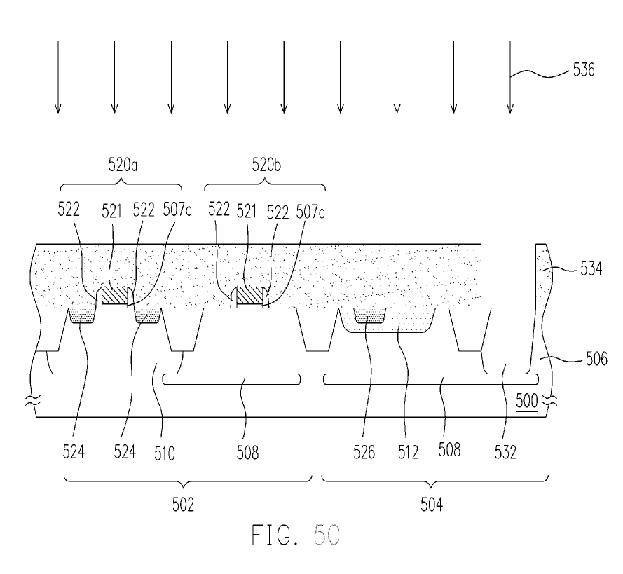

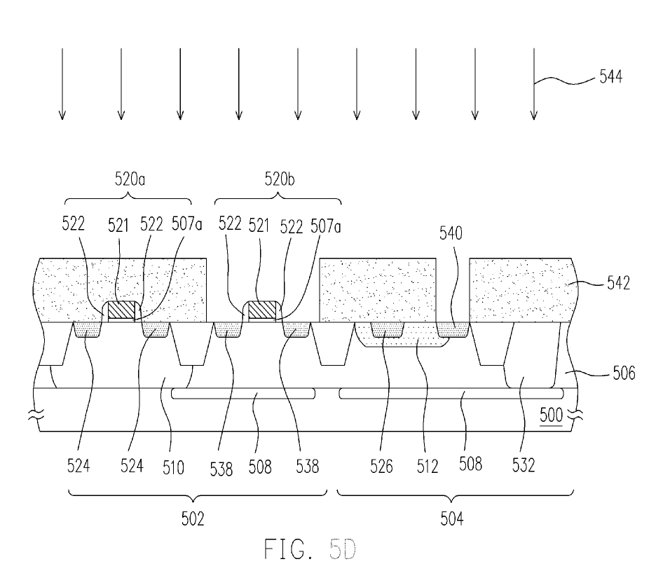

FIGS. 5A-5D are cross-sectional views of the process steps for fabricating a BiCMOS transistor according to another preferred embodiment of this invention. Referring to FIG. 5A, a substrate 500 having a CMOS transistor region 502 and a bipolar transistor region 504 is provided. If the substrate 500 is a P-type silicon substrate, a N-type epitaxial layer 506 and a dielectric layer 507 are formed in sequence on the substrate 500. Before forming the N-type epitaxial layer 506, a N-type buried layer 508 is formed within the substrate 500. In the CMOS transistor region 502, a P-well 510 is formed in the N-type epitaxial layer 506. In the bipolar transistor region 504, a base 512 is formed in the N-type epitaxial layer 506. The structure of the BiCMOS transistor is used as an example herein for the convenience of illustration; however, the scope of this invention is not limited by the exemplary structures described herein.

In FIG. 5A, the base 512 is formed in the N-type epitaxial layer 506 in the bipolar transistor region 504 by performing an ion implantation process 516 to the substrate 500 using a conductive photoresist pattern 514 as a mask. The base 512 is doped with P-type dopants, for example. The material of the conductive photoresist pattern 514 includes at least a conductive resin, a solvent and a photosensitive material. The conductive resin can be 3-hexylthiophene-3-thiophene-ethane methacrylate copolymer, for example. The solvent can be acetonitrile, and the photosensitive material can be gold chloride, for example. The conductive photoresist pattern 514 has a resistance smaller or equivalent to 10⁻⁶ ohm-cm. For example, the conductive photoresist pattern 514 can be either a positive photoresist or negative photoresist. After performing the ion implantation process, the conductive photoresist pattern 514 is removed.

Referring to FIG. 5B, gate structures 520a, 520b are formed on the N-type epitaxial layer 506 according to conventionally available methods. After forming the gate structures 520, an ion implantation process 530 is performed to the substrate using another conductive photoresist pattern 528 as a mask, so as to form N-type source/drain regions 524 in the N-type epitaxial layer 506 on both sides of the gate structure 520a above the P-well 510 and form N-type emitter 526 in the base 512. The gate structure 520a/520b includes a gate electrode 521, a gate oxide layer 507a and spacers 522. The material of the conductive photoresist pattern 528 can be the same as that of the conductive photoresist pattern 514. Afterwards, the conductive photoresist pattern 528 is removed.

Referring to FIG. 5C, a third ion implantation process 536 is performed to the substrate 500 using the conductive photoresist pattern 534 as a mask, so that a N-type collector contact 532 in the N-type epitaxial layer 506 in the bipolar transistor region 504. The material of the conductive photoresist pattern 534 can be the same as that of the conductive photoresist pattern 514. Afterwards, the conductive photoresist pattern 534 is removed.

Referring to FIG. 5D, a fourth ion implantation process 544 is performed to the substrate 500 using the conductive photoresist pattern 542 as a mask, so as to form P-type source/drain regions 538 in the N-type epitaxial layer 506 on both sides of the gate structure 520b above the N-buried layer 508 and form base contact 540 in the P-type base 512 that is between the N-type emitter 526 and the collector contact 532. The material of the conductive photoresist pattern 542 can be the same as that of the conductive photoresist pattern 514.

Herein, the base 512, the source/drain regions 524/the emitter 526, the collector contact 532, the source/drain regions 538/the base contact 540 are formed in sequence. The order of the process steps is not limited to the described order herein and can be switched or adjusted according to the process requirements. For example, the step for forming the heavily doped regions (such as, source/drain regions 538 and the base contact 540) at the same time can be divided into two or more different steps for forming the respective element. Similarly, two or more process steps can be combined and performed as one process step. Furthermore, the conductive photoresist pattern can be applied for the formation of other doped regions (such as, the buried layer) not described in details herein.

In conclusion, the conductive photoresist patterns described herein can be used to discharge the positive charges that are accumulated during the ion implantation process to external environments, so that local eruption of the positive charges or volcano effects can be avoided.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for reducing positive charges accumulated on a chip during an ion implantation process, comprising:
providing a substrate;
forming a conductive photoresist pattern over the substrate, wherein the conductive photoresist pattern exposes a portion of the substrate;
performing an ion implantation process to the substrate using the conductive photoresist pattern as a mask, so as to form a plurality of doped regions in the substrate; and
removing the conductive photoresist pattern.

2. The method according to claim 1, wherein a material of the conductive photoresist pattern comprises:
a conductive resin;
a solvent; and
a selectively photosensitive material.

3. The method according to claim 2, wherein the conductive resin includes 3-hexylthiophene-3-thiophene-ethane methacrylate copolymer.

4. The method according to claim 2, wherein, the solvent includes acetonitrile.

5. The method according to claim 2, wherein the photosensitive material includes gold chloride.

6. The method according to claim 1, wherein the conductive photoresist pattern has a resistance smaller or equivalent to 10⁻⁶ ohm-cm.

7. The method according to claim 1, wherein the conductive photoresist pattern is a positive photoresist layer.

8. The method according to claim 1, wherein the conductive photoresist pattern is a negative photoresist layer.

9. The method according to claim 1, wherein a concentration of the doped regions ranges from 10¹⁸ cm⁻³ to about 10²⁰ cm⁻³.

10. A method of fabricating a bipolar complementary metal-oxide-semiconductor (MOS) transistor, comprising forming a complementary MOS transistor and a bipolar transistor on a substrate, wherein the method is characterized in:
the step of forming heavily doped regions of the bipolar complementary MOS transistor comprises using a conductive photoresist pattern as a mask for an ion implantation process for preventing local eruptions of the bipolar complementary MOS transistor due to positive charges.

11. The method according to claim 10, wherein the heavily doped regions include source/drain regions.

12. The method according to claim 10, wherein the heavily doped regions include collector contacts.

13. The method according to claim 10, wherein the heavily doped regions include emitters.

14. The method according to claim 10, wherein the heavily doped regions include bases.

15. The method according to claim 10, wherein the heavily doped regions include base contacts.

16. The method according to claim 10, wherein a material of the conductive photoresist pattern comprises:
a conductive resin;
a solvent; and
a selectively photosensitive material.

17. The method according to claim 16, wherein the conductive resin includes 3-hexylthiophene-3-thiophene-ethane methacrylate copolymer.

18. The method according to claim 16, wherein, the solvent includes acetonitrile.

19. The method according to claim 16, wherein the photosensitive material includes gold chloride.

20. The method according to claim 10, wherein the conductive photoresist pattern has a resistance smaller or equivalent to 10⁻⁶ ohm-cm.

21. The method according to claim 10, wherein the conductive photoresist pattern is a positive photoresist layer.

22. The method according to claim 10, wherein the conductive photoresist pattern is a negative photoresist layer.
